(19) United States
(12) Patent Application Publication
(10) Pub. No.: US 2013/0337155 A1
(43) Pub. Date: Dec. 19, 2013

(54) MANUFACTURING METHOD OF CIRCUIT PATTERN

(71) Applicant: HSING YA HUANG, TAOYUAN COUNTY (TW)

(72) Inventor: HSING YA HUANG, TAOYUAN COUNTY (TW)

(73) Assignee: LEADING TECH COMMUNICATIONS INC., TAIPEI CITY (TW)

(21) Appl. No.: 13/525,438

(22) Filed: Jun. 18, 2012

(51) Int. Cl. H05K 3/10; H05K 3/14; C25D 5/02; H05K 3/12

(52) U.S. Cl. 427/98.4; 205/118

(57) ABSTRACT

This instant disclosure provides a manufacturing method of circuit pattern. The method comprising, forming a substrate; forming a protection layer on the substrate for making the protection layer to be a curved surface along the surface of the substrate; executing a pattern processing for the protection layer to make the protection layer to form a first pattern on the substrate, wherein a slot region is obtained according to the inner side of the first pattern; coating a macromolecule coating to the slot region for forming an activated metal layer on the substrate, wherein the activated metal layer forms a circuit pattern respective to the slot region, the macromolecule coating includes at least a kind of metal material; removing the protection layer for exposing the activated metal layer with the circuit pattern. The manufacturing quality of the circuit pattern can be improved and the associated cost can be saved.

### BACKGROUND OF THE INVENTION

1. Field of the Invention

The instant disclosure relates to a circuit pattern; in particular, to a manufacturing method of circuit pattern.

2. Description of Related Art

FIG. 1 and FIG. 2 show cross-sectional diagrams of a traditional antenna structure 100, 100′. As shown in FIG. 1, a laser direct structuring (LDS) process is applied to a substrate 11 to make a laser activated layer 12. The substrate 11 may be a casing of a mobile device (e.g. smart phone). The laser activated layer 12 may not accord to a predetermined line width (defined by the dashed lines) because some areas are not activated by the laser, thus a jump-plated phenomenon may be occurred. Therefore, the performance of the antenna may be affected. As shown in FIG. 2, when a laser beam L is applied to a via hole of the substrate 11 for making the laser activated layer 12, some area of the via hole wall may not be totally activated due to the diameter of the via hole, the shape of the via hole or the incident angle of the laser beam L, thus the laser activated layer 12 on the top surface and the laser activated layer 12 on the bottom surface may not connect to each other through the via hole or not in a good connection status. Therefore, the performance of the antenna may also be degraded accordingly. Thus, via holes with larger diameters are used when utilizing the laser direct structuring process. The mentioned disadvantages related to the antenna or the circuit pattern made by the laser direct structuring process needs to be further improved.

### SUMMARY OF THE INVENTION

The object of the instant disclosure is to offer a manufacturing method of circuit pattern for making a three-dimensional (or a curved surface) circuit pattern. Thus, the manufacturing quality of the circuit pattern could be improved and the associated cost could be cut down.

In order to achieve the aforementioned objects, according to an embodiment of the instant disclosure, a manufacturing method of circuit pattern is offered. The method comprises providing a substrate; forming a protection layer on the substrate, wherein the protection layer has the formation of curved surface structure along the curve of the surface of the substrate; executing a patterning processing for the protection layer to make the protection layer to form a first pattern on the substrate, wherein a slot region is obtained according to the inner side of the first pattern; coating a macromolecule coating in the slot region on the substrate to make an activated metal layer, in which the activated metal layer forms a circuit pattern corresponding to the shape of the slot region, and the macromolecule coating has at least a kind of metallic material; and removing the protection layer to make the activated metal layer with the circuit pattern to be exposed on the surface of the substrate.

In summary, manufacturing method may make a three-dimensional circuit pattern (or a curved surface pattern) on a substrate. The circuit pattern could have efficient binding strength to adhere to the substrate. The manufacturing quality of the circuit pattern could be improved and the associated cost could be cut down. The material of the substrate does not need to be restricted to any specific material. Additionally, the color cast caused by the conventional laser direct structuring could be avoided and the associated cost could be cut down.

In order to further the understanding regarding the instant disclosure, the following embodiments are provided along with illustrations to facilitate the disclosure of the instant disclosure.

### BRIEF DESCRIPTION OF THE DRAWINGS

FIG. 1 shows a cross-sectional diagram of a traditional antenna structure;

FIG. 2 shows a cross-sectional diagram of a traditional antenna structure;

FIG. 3 shows a flow diagram of a manufacturing method of circuit pattern according to an embodiment of the instant disclosure;

FIG. 4A shows a cross-sectional diagram of an antenna structure corresponding to the step of S300 according to an embodiment of the instant disclosure;

FIG. 4B shows a top-view diagram of an antenna structure corresponding to the step of S310 according to an embodiment of the instant disclosure;

FIG. 4C shows a cross-sectional diagram of an antenna structure corresponding to the step of S330 according to an embodiment of the instant disclosure;

FIG. 4D shows a cross-sectional diagram of an antenna structure corresponding to the step of S350 according to an embodiment of the instant disclosure;

FIG. 4E shows a cross-sectional diagram of an antenna structure corresponding to the step of S370 according to an embodiment of the instant disclosure;

FIG. 4F shows a cross-sectional diagram of an antenna structure corresponding to the step of S390 according to an embodiment of the instant disclosure.

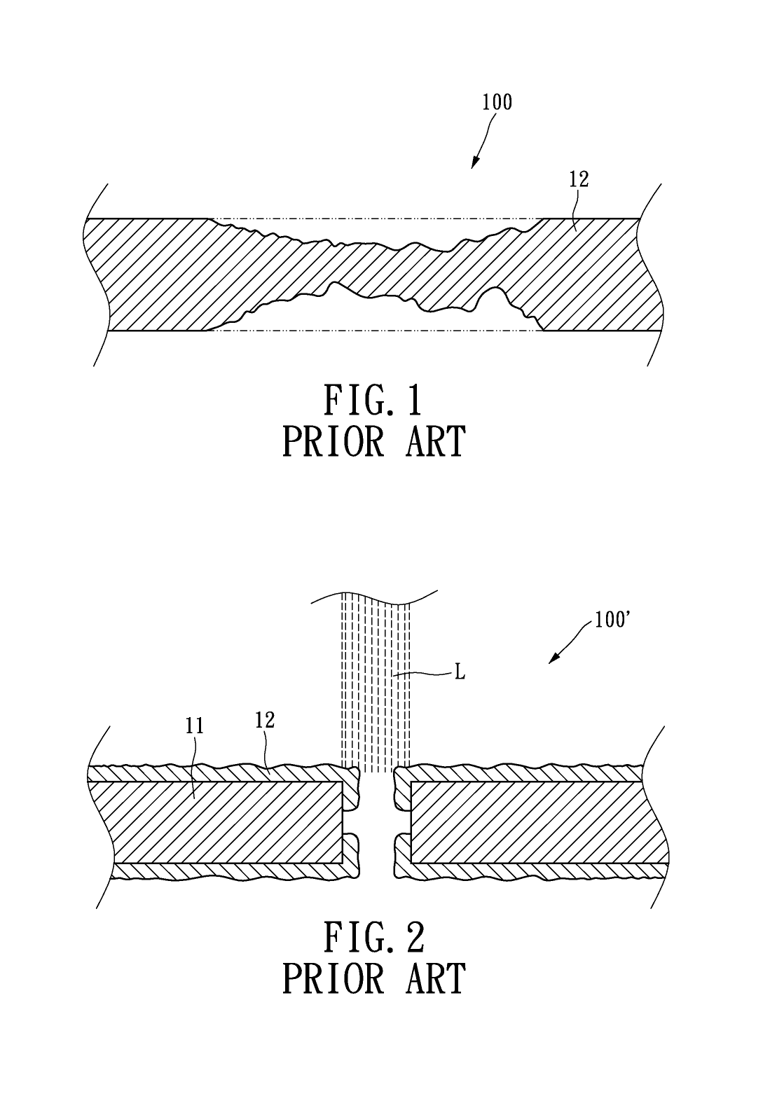

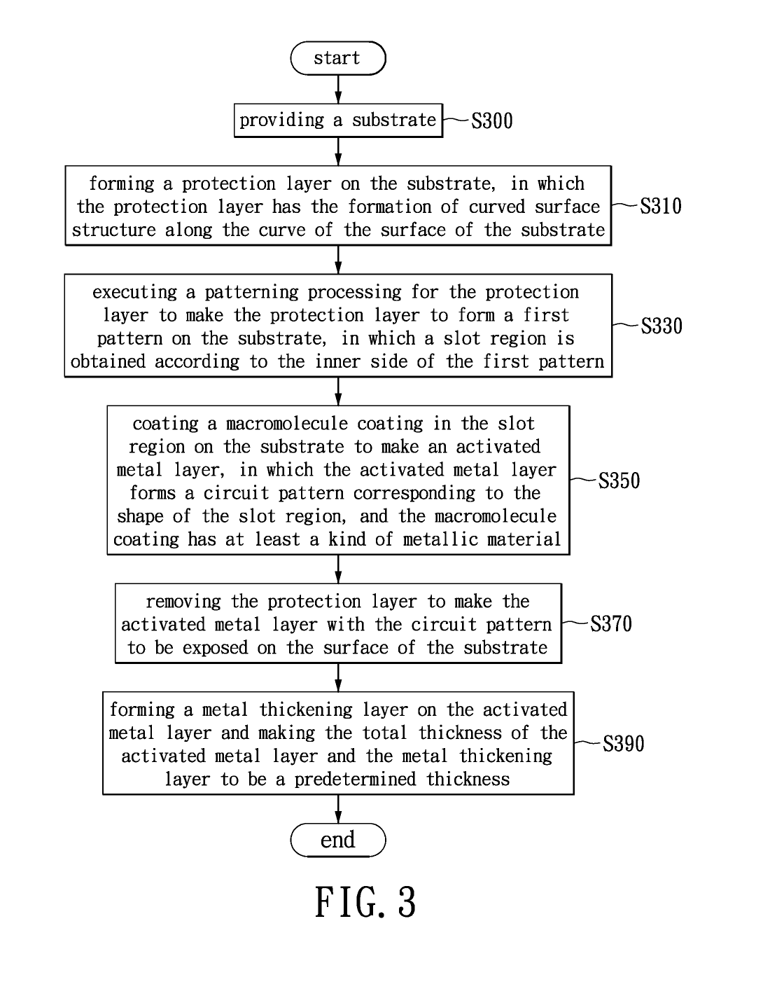

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

The instant disclosure provides a manufacturing method of circuit pattern. The method may be applied to making a three-dimensional or a curved circuit pattern on a substrate, such as an antenna structure. For ease of explanation, an antenna structure made by the manufacturing method is described in the following embodiment. However, this shouldn't be the limitation to the instant disclosure. In this embodiment, the substrate may be a casing of a smart phone, in which the casing of the smart phone usually is made by plastic or glass. However, the substrate material are not restricted thereto. In order to provide the circuit pattern with enough binding strength to the substrate, the antenna structure made on the casing (of the smart phone) is described as follows.

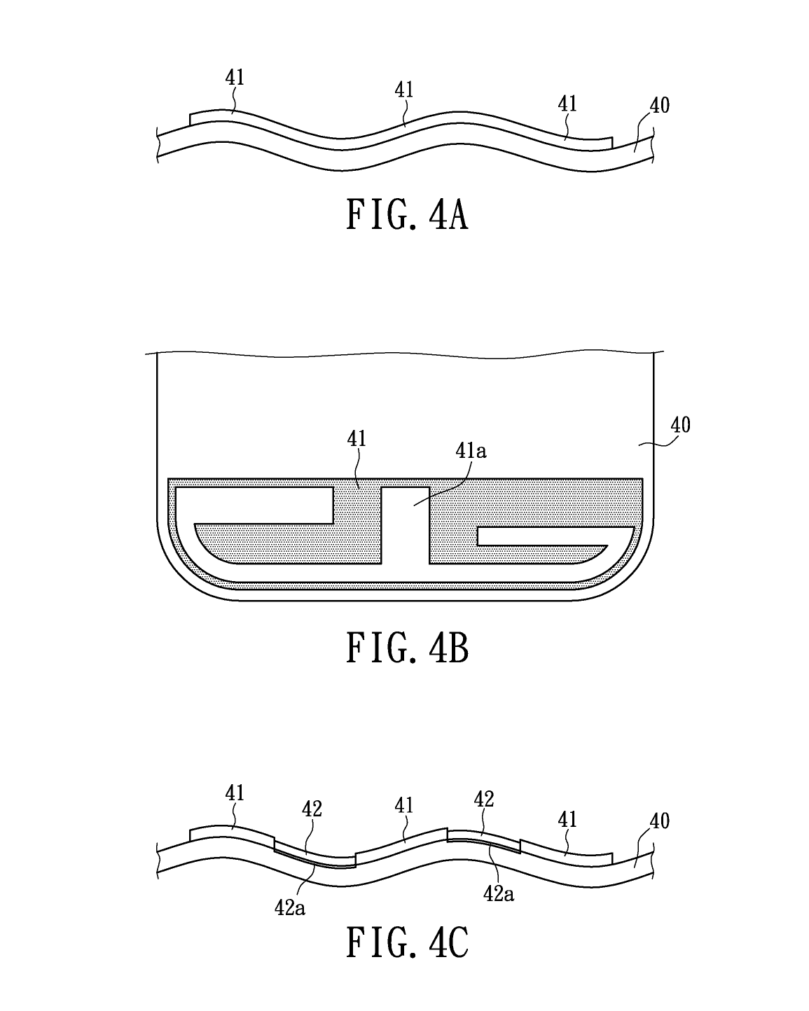

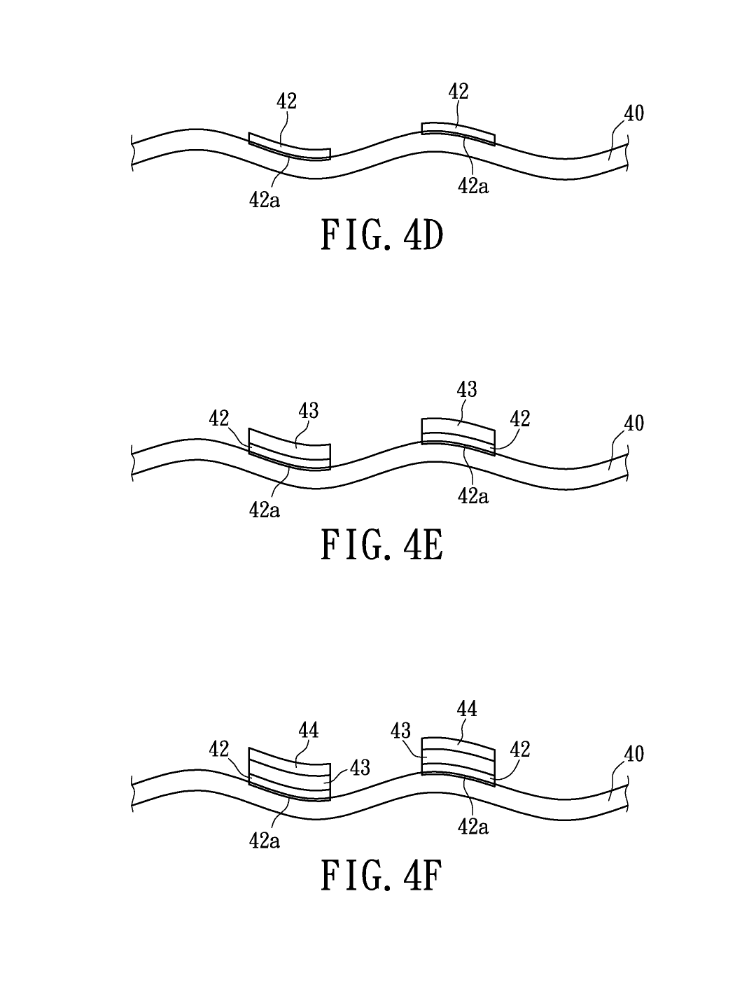

Please refer to FIGS. 3, 4A, 4B, 4C, 4D, 4E and 4F, FIG. 3 shows a flow diagram of a manufacturing method of antenna structure according to an embodiment of the instant disclosure. FIGS. 4A, 4B, 4C, 4D, 4E and 4F show the antenna structure corresponding to steps of S310 to S370. The manufacturing method of antenna structure comprising following steps. First, in step S300, providing a substrate, as shown in FIG. 4A. The substrate 40 may be a plastic substrate which is made by injection molding, but the manufacturing method and the material of making the substrate is not restricted thereto. For example: the substrate 40 may be made by polycarbonate (PC), Acrylonitrile Butadiene Styrene (ABS) or glass fiber. The substrate 40 may also be a glass substrate. The substrate 40 may have a predetermined shape in any shape (i.e., three dimensional shape), thus the antenna structure made on the substrate 40 may be also a three dimensional shape.

Please refer to FIGS. 3 and 4A. In step S310, forming a protection layer 41 on the substrate, in which the protection layer 41 has the formation of curved surface structure along the curve of the surface of the substrate 40. The protection layer 41 may be a photopolymerization type polymer or a thermoset type polymer. In this embodiment, the protection layer 41 may be accomplished by spray coating a wet film resist agent of thermal molding. Then, making thermal baking utilizing infrared ray to polymerizat the wet film resist agent for enhancing the binding strength of the resist agent. Or, utilizing a photopolymerization dry film and making hot molding, exposure and development to form a corrosion-resisted dry film.

Please refer to FIGS. 3 and 4B. In step S330, executing a patterning processing for the protection layer 41 to make the protection layer 41 to form a first pattern on the substrate 40, in which a slot region 41a is obtained according to the inner side of the first pattern. As shown in FIG. 4B, the first pattern formed by the protection layer 41 is the pattern of the dot area. The pattern formed by the slot region 41a (i.e., the shape of the slot region 41a shown in FIG. 4B) is the circuit pattern of the antenna structure. One implement manner for making pattern to the protection layer 41 is etching the protection layer 41 with a laser to make the protection layer 41 for forming the first pattern and removing part of the protection layer 41 excluding from the first pattern. The mentioned laser may be an yttrium orthovanadate (YVO₄) laser with wavelength of 1064 nm. It is worth mentioning that, for the traditional laser carving technique applying to the conductive circuit or metal circuit, the traditional laser carving technique may have to adjust the energy of the laser beam or scanning time of the laser beam in order not to damage the surface of the substrate 40 while finely removing the conductive circuit or metal circuit. Thus, the cost associated to the traditional laser carving technique could be increased accordingly.

Furthermore, when utilizing the mentioned yttrium orthovanadate (YVO₄) laser, the energy of the laser needs not to be adjusted as long as the energy of the laser is sufficient to remove the protection layer 41. Meanwhile, the laser energy for removing the protection layer 41 is less than the conventional laser energy for removing the conductive circuit or metal circuit. Thus, the laser energy of this embodiment is relative lower, such that the probability of damage to the substrate 40 may substantially decreased. However, the laser is not restricted thereto. For example, the laser may be a green light laser with wavelength of 532 nm.

Please refer to FIGS. 3 and 4C. In step S350, coating a macromolecule coating in the slot region 41a on the substrate 40 to make an activated metal layer 42, in which the activated metal layer 42 forms a circuit pattern (i.e., the circuit pattern of the antenna structure) corresponding to the shape of the slot region 41a, and the macromolecule coating has at least a kind of metallic material. In the step S350, the step may be accomplished by screen printing or spray finishing. For the method of screen printing, the circuit pattern may be directly obtained and the screen printing may effectively reduce the working hours and the associated cost. In a better embodiment, the metallic material in the macromolecule coating may be iron or copper for well binding to a metal thickening layer mentioned in the later steps. For example, the iron powder or the copper powder with polymethylmethacrylate (PMMA) or hard polyurethane elastomer (PU glue) could make the macromolecule coating. It is worth mentioning that in the step S350, a bonding polymer layer 42a is made when the macromolecule coating is coated on the substrate 40, as shown in FIG. 4C. The bonding polymer layer 42a is for increasing the binding strength between the activated metal layer 42 and the substrate 40.

Additionally, the metallic material in the macromolecule coating may be titanium (Ti), aluminum (Al), silver (Ag) or other metals, but the metallic material is not restricted thereto. No matter in what manner to coat the metallic material to the surface of the substrate 40, as long as the antenna structure could be well binding to the substrate 40 through the bonding polymer layer 42a. Accordingly, the good stability of the antenna structure could be obtained, the antenna may be easier to pass the stability testing, and the yield rate of manufacturing the antenna structure could be increased, too.

It is worth mentioning that, in the step S310, when the substrate 40 has a via hole (or via holes), the manufacturing method in this instant disclosure may reduce each used via hole to the range of 0.1 mm to 0.3 mm. Comparing to traditional process of making circuit pattern on the substrate, the manufacturing method of the instant disclosure may substantially to minimize the used via hole. In other words, when the substrate has at least one via hole and the size (or diameter) of the via hole ranges from 0.1 mm to 0.3 mm, the step S350 still could make activated metal layer 42 to be attached to the substrate 40, in which the metallic material may also attached to the inner surface of the via hole. Accordingly, the circuit patterns on difference surface of the substrate 40 could be electrically coupled. For example, a circuit pattern on the top surface of the substrate 40 may be electrically coupled a circuit pattern on the bottom surface of the substrate 40 through the via hole coated with metallic material. Further more, when making a panel planting process to thicken the activated metal layer 42, the mentioned via hole may be further reduced or be filled by the metallic material (e.g., filled by the copper), thus the via hole on the surface of the substrate 40 may be invisible for the human (e.g., the user of the mobile phone handling the phone casing). Therefore, the flatness could be improved and the visual appearance of the substrate 40 could be better. Especially when the substrate 40 is for the casing of a product (e.g., mobile phone), a beautiful visual appearance of the casing may be in agree with the consumer favorite, thus the product using the casing may be more competitive. Additionally, when the substrate 40 is for the casing of a product, a smaller via hole (or via holes) makes the water vapor outside the product be hard to permeate into the product for protecting the product.

Please refer to FIGS. 3 and 4D. In step S370, removing the protection layer 41 to make the activated metal layer 42 with the circuit pattern to be exposed on the surface of the substrate 40. Meanwhile, the thickness of the activated metal layer 42 may not enough for the antenna to operate in stable, thus the activated metal layer 42 may need to be thicken in the later process.

The protection layer 41 may be removed by using de-film liquid for example, using the de-film liquid to remove the dry film resist agent. The main component of the de-film liquid may be the sodium carbonate (Na₂CO₃) or potassium carbonate with PH higher than 13, but the instant disclosure is not restricted thereto. The de-film liquid may be a solvent, such as the sodium hydroxide (NaOH) solution, potassium hydroxide solution, amine ether or poly ethylene glycol (ethanolamine) . . . etc.

Please refer to FIGS. 3, 4E and 4F. In step S390, forming a metal thickening layer 43 on the activated metal layer 42 and making the total thickness of the activated metal layer 42 and the metal thickening layer 43 to be a predetermined thickness. The method of forming the metal thickening layer may be chemical plating or electroplating. For example, the copper may be plated on the activated metal layer 42 to obtain a copper layer with thickness ranges from 3 micrometers to 16 micrometers. Additionally, a metal protective layer 44 could be formed on the metal thickening layer 43 in order to protect the antenna structure (or the circuit pattern) after the step S390. The method of forming the metal protective layer 44 may be chemical plating or electroplating. The metal protective layer 44 may be a palladium layer, a nickel-palladium layer, a Ni—Au layer or a palladium layer with anticorrosive agent. The thickness of the metal protective layer 44 may be larger than 5 micrometers, but the instant disclosure is not restricted thereto. The thickness of the metal protective layer 44 may be altered depend on the design requirement.

The aforementioned embodiment illustrates the manufacturing method to make the antenna structure. However, the aforementioned manufacturing method may be applied to make a circuit pattern, such as a charge coupled device (CCD). The method could make a three-dimensional patterned conductive circuit on the usual plastic substrate or glass substrate. In other words, the instant disclosure does not restrict the use (or application) of the conductive circuit pattern made by the manufacturing method.

Accordingly, the aforementioned manufacturing method may make a three-dimensional circuit pattern (or a curved surface pattern) on a plastic substrate or a glass substrate. The circuit pattern could have efficient binding strength to attached to the substrate. The manufacturing quality of the circuit pattern could be improved and the associated cost could be cut down.

The material of the substrate does not need to be restricted to any specific material, the usual plastic (or glass) could be chosen to make the substrate, and the material cost of the substrate could be substantially reduced. In the manufacturing process, the applied protection layer could avoid the color cast caused by the conventional laser direct structuring and the associated cost could be cut down. Additionally, utilizing screen printing could diminish working hours and the cost of mass production. Further more, when the substrate has a via hole (or via holes), the via hole could be narrowed or be stuffed up for improving the flatness of the substrate, and the water vapor or the foreign matter could hard to permeate into the product (e.g., inner of the casing) through the narrowed or stuffed via hole.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims

1. A manufacturing method of circuit pattern, comprising:
providing a substrate made by plastic or glass, wherein the substrate has at least one via hole;
forming a protection layer on the substrate, wherein the protection layer has the formation of curved surface structure along a curve of the surface of the substrate;
executing a patterning processing for the protection layer by etching the protection layer with a low energy laser to make the protection layer to form a first pattern on the substrate and by removing part of the protection layer excluding from the first pattern, wherein a slot region is obtained according to the inner side of the first pattern;
coating a macromolecule coating in the slot region on the substrate to make an activated metal layer, in which the activated metal layer forms a circuit pattern corresponding to the shape of the slot region, and the macromolecule coating has at least a kind of metallic material, wherein the metallic material is attached to the inner surface of the via hole, and wherein a bonding polymer layer is made when the macromolecule coating is coated on the substrate, and the bonding polymer layer is for increasing the binding strength between the activated metal layer and the substrate; and
removing the protection layer to make the activated metal layer with the circuit pattern to be exposed on the surface of the substrate.

2. The manufacturing method of circuit pattern according to claim 1, wherein after removing the protection layer further comprises:
forming a metal thickening layer on the activated metal layer and making the total thickness of the activated metal layer and the metal thickening layer to be a predetermined thickness.

3. The manufacturing method of circuit pattern according to claim 2, wherein the method of forming the metal thickening layer is chemical plating or electroplating.

4. The manufacturing method of circuit pattern according to claim 2, wherein the metal thickening layer is a copper layer with thickness ranges from three micrometers to sixteen micrometers.

5. The manufacturing method of circuit pattern according to claim 1, wherein the step of coating the macromolecule coating in the slot region on the substrate to make the activated metal layer is accomplished by screen printing or spray finishing.

6. The manufacturing method of circuit pattern according to claim 1, wherein the metallic material of the macromolecule coating is copper, iron or silver.

7. (canceled)

8. (canceled)

9. The manufacturing method of circuit pattern according to claim 2, further comprising:
forming a metal protective layer on the metal thickening layer.

10. The manufacturing method of circuit pattern according to claim 9, wherein the method of forming the metal protective layer is electroplating.

11. The manufacturing method of circuit pattern according to claim 1, wherein the low energy laser is yttrium orthovanadate laser.

12. The manufacturing method of circuit pattern according to claim 1, wherein the low energy laser is green light laser.

13. The manufacturing method of circuit pattern according to claim 1, wherein the diameter of the via hole ranges from 0.1 mm to 0.3 mm.

14. The manufacturing method of circuit pattern according to claim 1, wherein the via hole is narrowed by the metallic material.

15. The manufacturing method of circuit pattern according to claim 1, wherein the via hole is stuffed up by the metallic material.
